(19) United States
(12) Patent Application Publication
(10) Pub. No.: US 2007/0267696 A1
(43) Pub. Date: Nov. 22, 2007

(54) Mobile transforming plug

(76) Inventor: Sheng-Hsin Liao, Shulin City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/409,977

(22) Filed: Apr. 25, 2006

(51) Int. Cl. H01L 27/12

(52) U.S. Cl. 257/347

(57) ABSTRACT

A mobile transforming plug includes an insulating main body, a shell cover, a linking element and a linker. At the front side of the insulating main body, a connecting part is formed. A carrying part is formed at the rear side of the insulating main body. There is a connection area on the carrying part. The front two sides of the insulating main body each have a concave slot and a wedging-buckling end. A wedge extends from each of the two sides of the shell cover. The wedges are positioned in the concave slots and are wedged movably at the wedging-buckling end. The linking element is located at the connection area and connected with the pins. The linker is linked with the linking element. Thereby, the plug is plugged movably with the Internet or telephone plug. It can be plugged movably with the external plughole of electronic information products.

### BACKGROUND OF THE INVENTION

1. Field of the Invention

The present invention relates to a plug. In particular, this invention relates to a mobile transforming plug that can link with an Internet plug and be plugged into an electronic information product.

2. Description of the Related Art

Taiwan patent TW374512 discloses a mobile telephone line connection base. The prior art includes a base and an upper cover. There are a plurality of metal conducting lines that pass through the front and back ends of the base. At the side surface of the base, there is a buckling-joining hole. The upper cover is wedged movably with the base. A fastener extends from each of the two sides of the upper cover. The fastener can be plugged in to the base, and buckled and joined with the buckling-joining hole. The fastener can move upward and downward within the buckling-joining hole. Thereby, the front side and the back side of the base can individually and movably plug with a telephone line plug to provide a transforming-linking function for telephone lines or Internet lines.

However, the mobile telephone line connection base of the prior art only provides the transforming-linking function for telephone lines or Internet lines. It cannot be plugged and connected with electronic information products, such as laptops, PCs or PDAs. Recently, manufacturers of such electronic information products have begun producing smaller and more compact products by simplifying the peripheral components. The prior art providing the transforming-linking function for telephone lines or Internet lines does not match the requirements of the manufacturers of these electronic information products.

### SUMMARY OF THE INVENTION

One particular aspect of the present invention is to provide a mobile transforming plug. The present invention provides the plug with a smart structure. The plug is portable and is movably plugged with the Internet or a telephone plug. It can be movably plugged with electronic information products, such as laptops, PCs or PDAs. Therefore, the components are simplified.

The mobile transforming plug includes an insulating main body, a shell cover, a linking element, and a linker. At the front side of the insulating main body, a connecting part is formed and a plurality of pins are included. A carrying part is formed at the rear side of the insulating main body. On the carrying part, there is a connection area. The front two sides of the insulating main body, each have a concave slot and a wedging-buckling end. A wedge extends from each of the two sides of the shell cover. The wedges are positioned in the concave slots and are wedged movably at the wedging-buckling end. The linking element is located at the connection area and connected with the pin. The linker is linked and joined on the carrying part and the linker is linked and joined with the linking element.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide a further understanding of the invention. A brief introduction of the drawings is as follows:

FIG. 1 is an exploded perspective view of the insulating main body and the shell cover of the present invention;

FIG. 2 is a perspective view of the insulating main body and the shell cover of another embodiment of the present invention;

FIG. 3 is a top view of the insulating main body of the present invention;

FIG. 4 is a perspective view of the carrying part of the present invention;

FIG. 5 is an assembly view of the linking element connecting and joining with the linker of the present invention;

FIG. 6 is another assembly view of the linking element connecting and joining with the linker of the present invention;

FIG. 7 is an assembly perspective view of the first embodiment of the present invention linking with the linker;

FIG. 8 is an assembly perspective view of the second embodiment of the present invention linking with the linker;

FIG. 9 is an assembly perspective view of the third embodiment of the present invention linking with the linker;

FIG. 10 is an exploded perspective view of the present invention linking with a line-wrapped disk;

FIG. 11 is a cross-sectional view of the insulating main body of the present invention;

FIG. 12 is a cross-sectional view of the insulating main body of another embodiment of the present invention; and

FIG. 13 is a cross-sectional view of the present invention wedging with the carrying part and the shell cover.

### DETAILED DESCRIPTION OF THE PREFERRED EMBODIMENTS

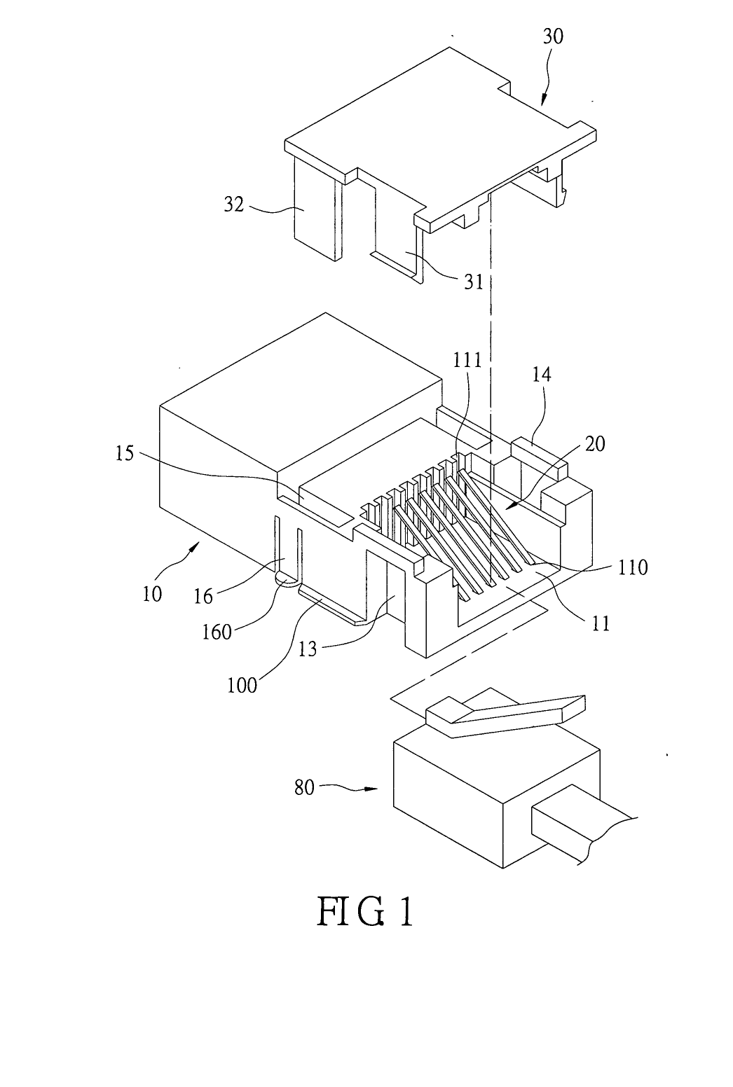

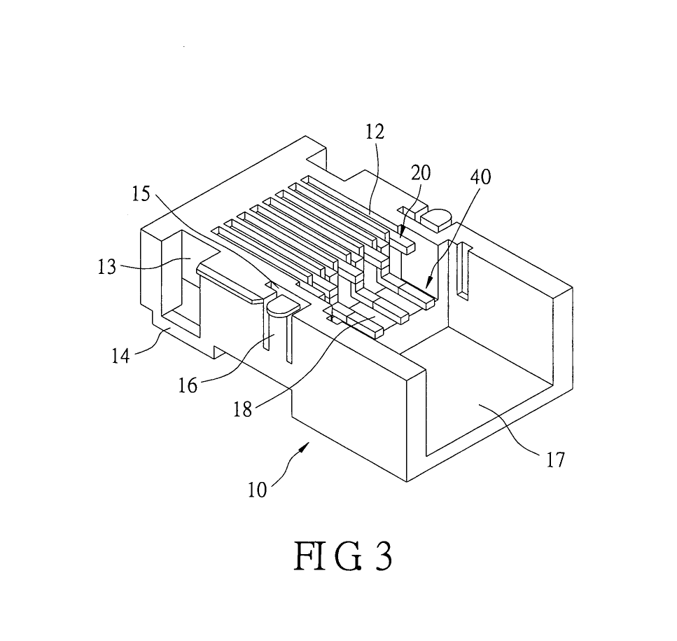

Please refer to FIG. 1 and FIG. 3. The mobile transforming plug includes an insulating main body 10, a shell cover 30, and a linking element 40. The insulating main body 10 is made of insulating materials, such as plastic. At the front side of the insulating main body 10, a connecting part 11 is formed downward. There are a plurality of pins 20 on the connecting part 11. On the connecting part 11A, there are also a plurality of pinholes 110 and slots 111. The pinholes 110 and slots 111 are disposed equidistant from each other along the insulating main body 10, and the slots 111 correspond to the pinholes. On the bottom of the insulating main body 10, a plurality of pin-slots 12 are formed that are adjacent to the pinholes 110. The pin-slots 12 are disposed equidistant from each other on the bottom of the insulating main body 10e. The pins pass through the pinholes 110 and are located in the pin-slots 12, and correspond to the slot 111. The pin 20 is made of conducting materials, such as copper.

The shell cover 30 is made of insulating materials, such as plastic. A wedge 31 and a convex rib 32 extend from each of the two sides of the shell cover 30. On the front two sides of the insulating main body 10, there is a concave slot 13, a wedging-buckling end 14 and a plughole 15. The wedging-buckling end 14 is fastened above the concave slot 13. The wedges 31 are positioned in the concave slots 13 and are wedged movably at the wedging-buckling end 14 within the concave slots 13. The plugholes 15 are located at one side of the wedging-buckling ends 14. At the two sides of the insulating main body 10, there is a pressing rib 16. The pressing ribs 16 individually correspond to the outside of the plugholes 15. The convex ribs 32 are individually positioned in the plugholes 15. The pressing ribs 16 flexibly press the convex ribs 32 of the shell cover 30. Thereby, the shell cover 30 is movably positioned at the connecting part 11 of the insulating main body 10 and is hollow. A movably plug 80 for plugging into Internet or telephone lines contacts the pins 20 to make the Internet or telephone plug 80 electrically connect with the pins 20.

A first extended flake 100 extends outward with a distance from the bottom of each of the right and left sides of the insulating main body 10. A second extended flake 160 extends outward with a distance from the bottom of each of the pressing ribs.

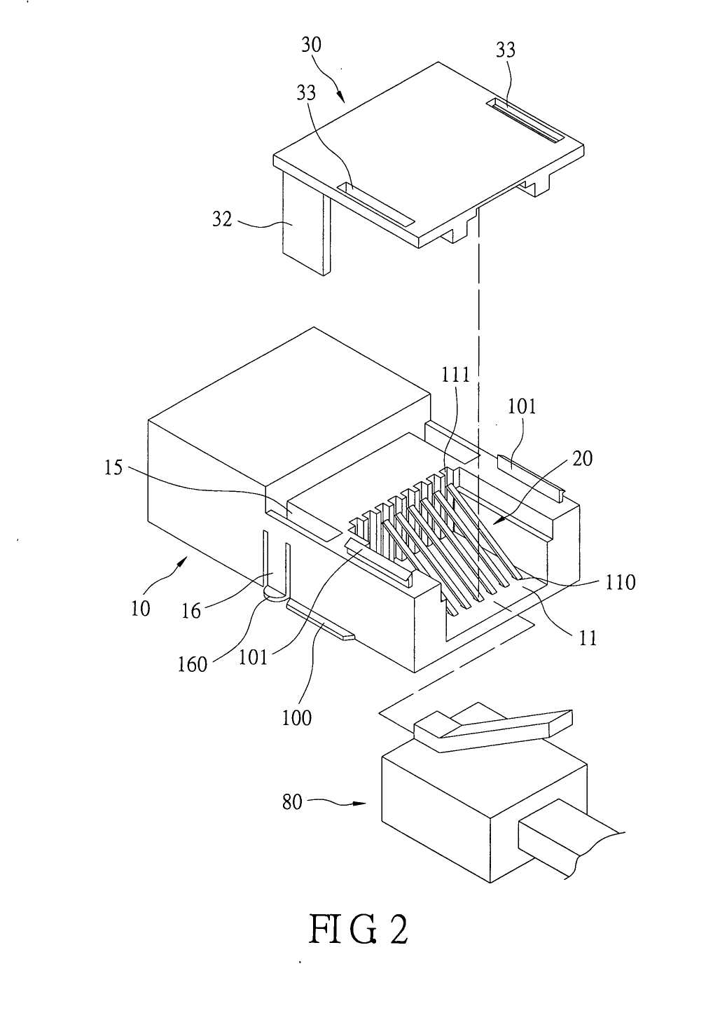

Please refer to FIG. 2, which shows a perspective view of the insulating main body and the shell cover of another embodiment of the present invention. Another wedge 101 extends upward from each of the two sides of the insulating main body 10. The wedges 101 correspond to the connecting part 11. At the right and left sides of the shell cover 30 there is a through hole 33. The through holes 33 individually and movably pass through the wedges 101 to make the shell cover 30 fasten onto the insulating main body 10 to achieve the described function.

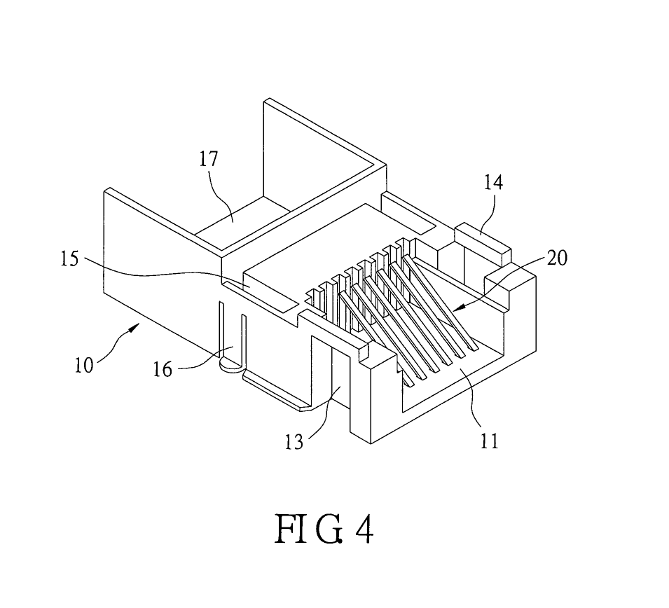

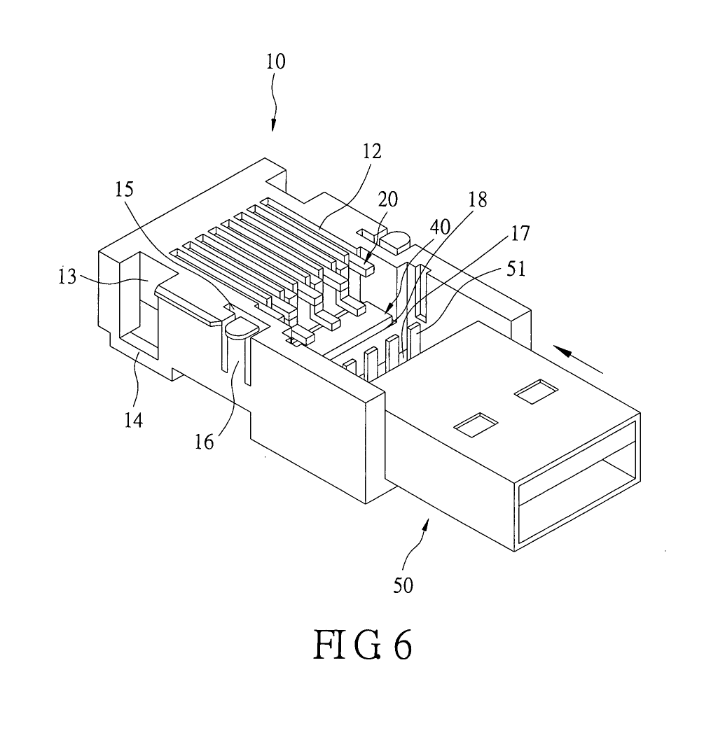

As shown in FIG. 3, a carrying part 17 is formed at the rear side of the insulating main body 10. The carrying part 17 has a concave shape in the direction that is opposite to the connecting part 11. Alternatively, the carrying part 17 has the same direction with the connecting part 11 and has a concave shape (as shown in FIG. 4). On the carrying part 11, there is a connection area 18. The connection area 18 is adjacent to the pin-slots 12 and protrudes onto the insulating main body 10. The linking element 40 is located at the connection area 18. The linking element 40 can be a plurality of conducting metals, a PCB (as shown in FIG. 6), or a plurality of lines (not shown in the figure). The linking element 40 is connected with the pins 20 via a welding method to locate the pins 20 on the connection area 18 thereby making the linking element 40 electrically connect with the pins 20.

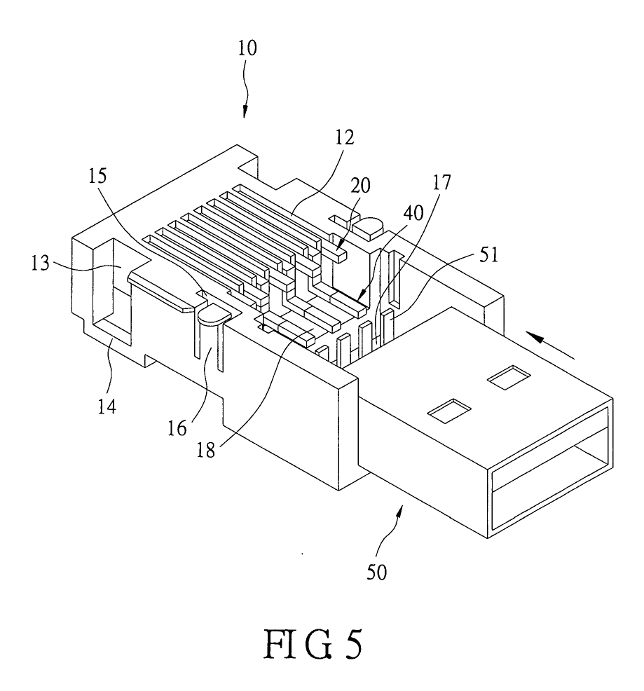

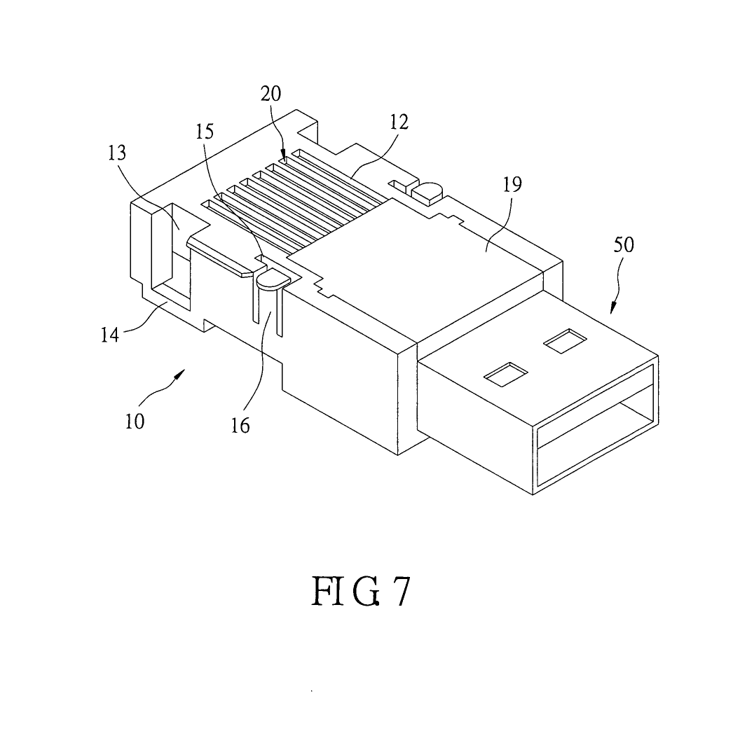

The carrying part 17 can link and join with a variety of linkers 50. As shown in FIG. 5, which shows an assembly view of the linking element connecting and joining with the linker 50 of the first embodiment of the present invention. The linker 50 can be a USB or a Mini USB. There are a plurality of pins 51 at the rear side of the linker 50. The pins 51 of the linker 50 are linked and joined with the linking element 40 via a welding method to make the linker 50 electrically connect with the pins 20. After the linker 50 electrically connects with the pins 20, an insulating layer 19 (as shown in FIG. 7) is covered. The insulating layer 19 covers the pins 51 of the linker 50 and the linking element 40 to protect the linker 50 and the linking element 40. The insulating layer 19 is made of plastic or rubber. Alternatively, after the linker 50 links and joins with the linking element 40, a carrying part shell cover 30′ is movably wedged. The insulting main body 10 wedges with the carrying part shell cover 30′ and corresponds to the carrying part 17. The carrying part shell cover 30′ covers the pins 51 of the linker 50 and the linking element 40 to achieve the described function.

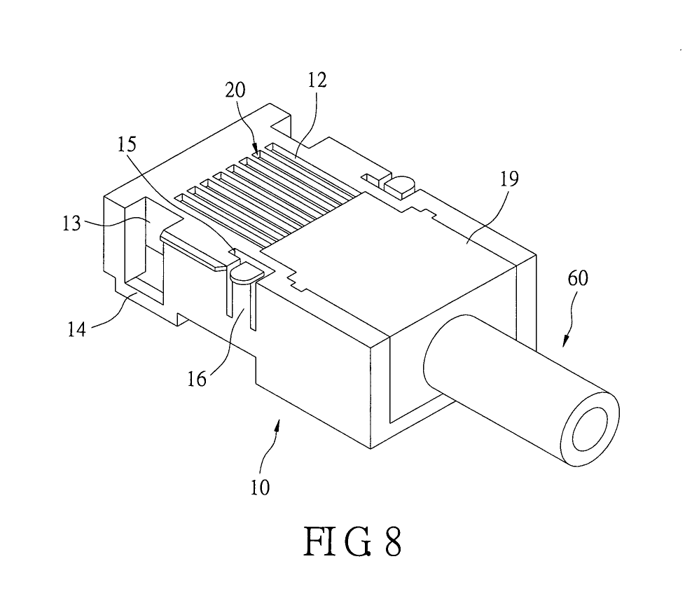

Please refer to FIG. 8, which shows an assembly perspective view of the second embodiment of the present invention linking with the linker 60. The linker 60 is a DC plug. After the linker 60 links and joins with the carrying part 17 to achieve the electrical connection, an insulating layer 19 is covered to protect the linker 60 and the linking element 40 located in the insulating main body 10 (not shown in the figure). Alternatively, the insulting main body 10 wedges with the carrying part shell cover 30′ to achieve the same function (not shown in the figure).

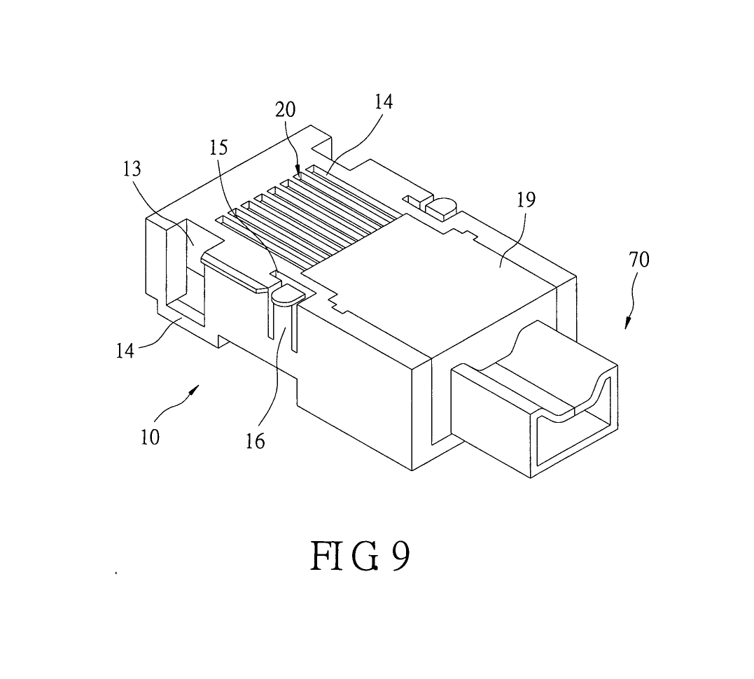

Please refer to FIG. 9, which shows an assembly perspective view of the third embodiment of the present invention linking with the linker 70. The linker 70 is an IEEE 1394 plug. After the linker 70 links and joins with the carrying part 17 to achieve the electrical connection, an insulating layer 19 is covered to protect the linker 70 and the linking element 40 located in the insulating main body 10 (not shown in the figure). Alternatively, the insulting main body 10 wedges with the carrying part shell cover 30′ to achieve the same function (not shown in the figure).

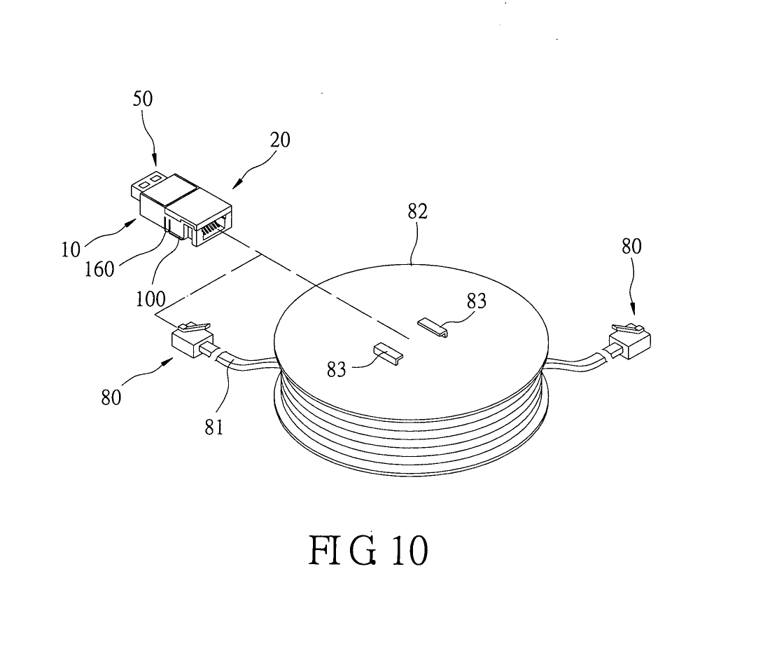

Please refer to FIG. 10. The first extended flakes 100 and the second extended flakes 160 are used for wedging movably the insulating main body 10 with a line-wrapped disk 82. On the proper location of the surface of the line-wrapped disk 82, there are two wedging parts 83 that correspond to each other. The first extended flakes 100 and the second extended flakes 160 are slidably wedged in the wedging part 83 to make the insulating main body 10 steadily wedge on the line-wrapped disk 82. The line-wrapped disk 82 is used for receiving the Internet or telephone plug 80 and its conducting line 81.

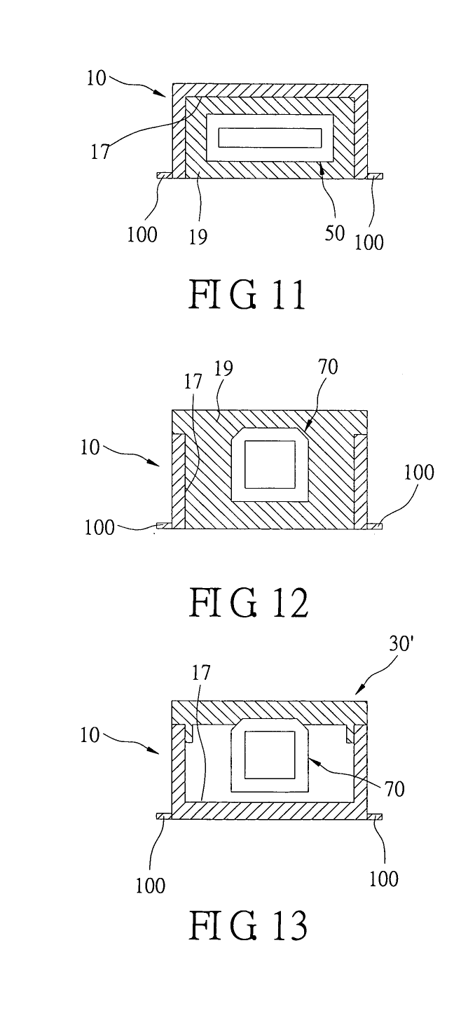

Please refer to FIG. 11 and FIG. 12. Because the linkers 50 and 70 are different, the thickness of the linkers is different. Moreover, the same linker 70 still has different formats (as shown in FIG. 9 and FIG. 12). The upper and lower sides of the carrying 17 of the present invention have a hollow shape. After the linker 70 is linked and joined with the linking element 40, an insulating layer 19 is covered. Thereby, the present invention matches the linker 70 that has a different format or a different size.

The present invention provides the plug with a smart structure. The plug is also portable. The plug can be movably plugged with a plughole of electronic information products, such as laptops, PCs or PDAs via a linker to provide the navigating Internet function. Thereby, computer manufacturers can simplify the component of the Internet plug and reduce the thickness of the product to make the product smaller and more compact. The required manufacturing time is also less than the prior art.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A mobile transforming plug, comprising:
an insulating main body, wherein a connecting part is formed at front side of the insulating main body and a plurality of pins are included and a carrying part is formed at the rear side of the insulating main body, there is a connection area on the carrying part, and a concave slot and a wedging-buckling end on each of two front sides of the insulating main body;
a shell cover, wherein a wedge extends from the two sides of the shell cover, and the wedges are positioned in the concave slots and are wedged movably at the wedging-buckling end;
a linking element located at the connection area and connected with the pin; and
a linker linked and joined on the carrying part, wherein the linker is linked and joined with the linking element.

2. The mobile transforming plug as claimed in claim 1, wherein the number of the pins is greater than one, and there are a plurality of pinholes and slots on the connecting part, wherein the slots correspond to the pinholes, a plurality of pin-slots are formed on the bottom of the insulating main body and are adjacent to the pinholes, and the pins that pass through the pinholes, are located in the pin-slots and correspond to the slot.

3. The mobile transforming plug as claimed in claim 1, wherein a convex rib extends from each of the two sides of the shell cover and a plughole is located at each of the front two sides of the insulating main body, wherein the convex ribs are positioned in the plugholes.

4. The mobile transforming plug as claimed in claim 3, wherein a pressing rib is located at each of the two sides of the insulating main body and the pressing ribs individually correspond to the outside of the plugholes, and the pressing ribs press the convex ribs of the shell cover.

5. The mobile transforming plug as claimed in claim 4, wherein a first extended flake extends outward from the bottom of each of the two sides of the insulating main body, and a second extended flake extends outward from the bottom of each of the pressing ribs.

6. The mobile transforming plug as claimed in claim 1, wherein the carrying part has a concave shape in the direction that is opposite to the connecting part, wherein after the linker is connected with the linking element, an insulating layer is covered and the insulating layer covers the linker and the linking element.

7. The mobile transforming plug as claimed in claim 6, wherein the insulating layer is made of plastic or rubber.

8. The mobile transforming plug as claimed in claim 1, wherein the carrying part has a concave shape in the direction that is same as the connecting part, wherein after the linker is connected with the linking element, an insulating layer is covered and the insulating layer covers the linker and the linking element.

9. The mobile transforming plug as claimed in claim 8, wherein the insulating layer is made of plastic or rubber.

10. The mobile transforming plug as claimed in claim 1, wherein the carrying part is hollow, wherein after the linker is connected with the linking element, an insulating layer is covered and the insulating layer covers the linker and the linking element.

11. The mobile transforming plug as claimed in claim 10, wherein the insulating layer is made of plastic or rubber.

12. The mobile transforming plug as claimed in claim 1, wherein the carrying part has a concave shape in the direction that is opposite to the connecting part, wherein after the linker is connected with the linking element, the linker movably wedges with a carry part shell cover and the carry part shell cover covers the linker and the linking element.

13. The mobile transforming plug as claimed in claim 1, wherein the carrying part has a concave shape in the direction that is same as the connecting part, wherein after the linker is connected with the linking element, the linker movably wedges with a carry part shell cover and the carry part shell cover covers the linker and the linking element.

14. The mobile transforming plug as claimed in claim 1, wherein the linking element is a conducting metal, a PCB, or a connecting line.

15. The mobile transforming plug as claimed in claim 1, wherein the linker is a USB, a Mine USB, a DC plug or an IEEE 1394 plug.

16. A mobile transforming plug, comprising:
an insulating main body, wherein a connecting part is formed at front side of the insulating main body and a plurality of pins are included and a carrying part is formed at the rear side of the insulating main body, there is a connection area on the carrying part, and a wedge extends upward from each of the two front sides of the insulating main body;
a shell cover, wherein a through hole is located at each of the two sides of the shell cover, and the through holes movably and individually pass through the wedges;
a linking element located at the connection area and connected with the pin; and
a linker linked and joined on the carrying part, wherein the linker is linked and joined with the linking element.

17. The mobile transforming plug as claimed in claim 16, wherein the number of the pins is greater than one, and there are a plurality of pinholes and slots on the connecting part, wherein the slots correspond to the pinholes, a plurality of pin-slots are formed on the bottom of the insulating main body and are adjacent to the pinholes, and the pins that pass through the pinholes, are located in the pin-slots and correspond to the slot.

18. The mobile transforming plug as claimed in claim 16, wherein a convex rib extends from each of the two sides of the shell cover and a plughole is located at each of the front two sides of the insulating main body, wherein the convex ribs are positioned in the plugholes.

19. The mobile transforming plug as claimed in claim 18, wherein a pressing rib is located at each of the two sides of the insulating main body and the pressing ribs individually correspond to the outside of the plugholes, and the pressing ribs press the convex ribs of the shell cover.

20. The mobile transforming plug as claimed in claim 19, wherein a first extended flake extends outward from the bottom of each of the two sides of the insulating main body, and a second extended flake extends outward from the bottom of each of the pressing ribs.

21. The mobile transforming plug as claimed in claim 16, wherein the carrying part has a concave shape in the direction that is opposite to the connecting part, wherein after the linker is connected with the linking element, an insulating layer is covered and the insulating layer covers the linker and the linking element.

22. The mobile transforming plug as claimed in claim 21, wherein the insulating layer is made of plastic or rubber.

23. The mobile transforming plug as claimed in claim 16, wherein the carrying part has a concave shape in the direction that is same as the connecting part, wherein after the linker is connected with the linking element, an insulating layer is covered and the insulating layer covers the linker and the linking element.

24. The mobile transforming plug as claimed in claim 23, wherein the insulating layer is made of plastic or rubber.

25. The mobile transforming plug as claimed in claim 16, wherein the carrying part is hollow, wherein after the linker is connected with the linking element, an insulating layer is covered and the insulating layer covers the linker and the linking element.

26. The mobile transforming plug as claimed in claim 25, wherein the insulating layer is made of plastic or rubber.

27. The mobile transforming plug as claimed in claim 16, wherein the carrying part has a concave shape in the direction that is opposite to the connecting part, wherein after the linker is connected with the linking element, the linker movably wedges with a carry part shell cover and the carry part shell cover covers the linker and the linking element.

28. The mobile transforming plug as claimed in claim 16, wherein the carrying part has a concave shape in the direction that is same as the connecting part, wherein after the linker is connected with the linking element, the linker movably wedges with a carry part shell cover and the carry part shell cover covers the linker and the linking element.

29. The mobile transforming plug as claimed in claim 16, wherein the linking element is a conducting metal, a PCB, or a connecting line.

30. The mobile transforming plug as claimed in claim 16, wherein the linker is a USB, a Mini USB, a DC plug, or an IEEE 1394 plug.
